(19) United States
(12) Patent Application Publication
(10) Pub. No.: US 2011/0174084 A1
(43) Pub. Date: Jul. 21, 2011

(54) METHODS AND SYSTEMS FOR MEASURING STATE OF CHARGE

(75) Inventors: Jon K. West, Gainesville, FL (US); Daniel J. West, Gainesville, FL (US); Julius Regalado, Gainesville, FL (US); Nelson Citta, Lake City, FL (US)

(73) Assignee: G4 SYNERGETICS, INC., Roslyn, NY (US)

(21) Appl. No.: 13/006,708

(22) Filed: Jan. 14, 2011

Related U.S. Application Data
(60) Provisional application No. 61/295,412, filed on Jan. 15, 2010.

(51) Int. Cl. G01L 5/08; G01L 1/00; G01R 11/04

(52) U.S. Cl. 73/862.581; 73/862.381; 324/157

(57) ABSTRACT

Charge information associated with an energy storage device may be determined from one or more kinetic responses of the energy storage device. Kinetic responses may include displacements, forces, pressures, or other kinetic properties, and changes in properties thereof. An indication device, such as a sensor, transducer, or other device, may be used to indicate kinetic responses. Charge information, measurements, or both, may be derived from indications of kinetic responses. Charging or discharging of an energy storage device may be controlled based on charge information.

### CROSS-REFERENCE TO RELATED APPLICATIONS

This application claims the benefit of U.S. Provisional Application No. 61/295,412 filed Jan. 15, 2010, which is hereby incorporated by reference herein in its entirety.

### FIELD OF THE INVENTION

The present invention relates to measuring charge information of energy storage devices, and more particularly to measuring kinetic responses of energy storage devices to determine state of charge.

### BACKGROUND OF THE INVENTION

Electrodes are used to supply and remove electrons from some medium. Electrochemical cells use electrodes to facilitate electron transport and transfer during electrochemical interactions. Energy storage devices may use electrodes in both galvanic and electrolytic capacities, corresponding to discharging or charging processes, respectively. Energy storage devices can be characterized by an energy capacity, which is the amount of energy that may be stored or released by the device during charging and discharging, respectively.

The state of charge of an energy storage device represents a progress variable indicating the extent of charge or discharge relative to the energy capacity. Typically, state of charge is determined or estimated by measuring the operating voltage of the electrochemical storage device. However, the operating voltage of some electrochemical storage devices may be relatively insensitive to state of charge in certain operating regimes.

### SUMMARY OF THE INVENTION

In view of the foregoing, provided are techniques, arrangements, and apparatuses for determining charge information for an energy storage device. Charge information may include state of charge, indications of robustness, cycle number, any other information associated with a suitable energy storage device (ESD), or any combination thereof.

In some embodiments, one or more kinetic responses such as, for example, displacement, pressure, force, or changes thereof may be indicated by any suitable indication device. An indication device may be any suitable type of linear displacement sensor, pressure transducer, force transducer, optical sensor, any other suitable indication device, or any combination thereof. In some embodiments, processing circuitry may be used to determine a measurement value based at least in part on a received signal from an indication device. Charge information may be derived from a received indication signal by suitable processing circuitry.

In some embodiments, charge information may be used to control the state of charge, or changes thereof (e.g., charging or discharging), of an ESD. A measurement of a suitable kinetic response may be determined by a suitable measurement device. The measurement device may include an indication device, processing circuitry, any other suitable components, or any suitable combination thereof, which may be used to determine a measurement of a kinetic response. Charge information regarding an ESD may be determined by the control system based at least in part on the kinetic response measurement. The control system may charge or discharge the ESD based at least in part on the charge information. For example, in some embodiments, the control system may set, limit, cease or otherwise manage charging characteristics (e.g., charge, rate of charge) applied to the ESD. Likewise, discharge characteristics may be controlled by the control system.

### BRIEF DESCRIPTION OF THE DRAWINGS

The above and other objects and advantages of the invention will be apparent upon consideration of the following detailed description, taken in conjunction with the accompanying drawings, in which like reference characters refer to like parts throughout, and in which:

FIG. 1 shows a schematic cross-sectional view of an illustrative structure of a bipolar electrode-unit (BPU) in accordance with some embodiments of the present invention;

FIG. 2 shows a schematic cross-sectional view of an illustrative structure of a stack of BPUs of FIG. 1 in accordance with some embodiments of the present invention;

FIG. 3 shows a schematic cross-sectional view of an illustrative structure of a monopolar electrode-unit (MPU) in accordance with some embodiments of the present invention;

FIG. 4 shows a schematic cross-sectional view of an illustrative structure of a device containing two MPUs of FIG. 3 in accordance with some embodiments of the present invention;

FIG. 5 shows an illustrative electrode structure with a cutaway section in accordance with some embodiments of the present invention;

FIG. 6 shows a top plan view of an illustrative energy storage device (ESD) in accordance with some embodiments of the present invention;

FIG. 7 shows a cross-sectional view of the elements of FIG. 6, taken from line VII-VII, in accordance with some embodiments of the present invention;

FIG. 8 shows a cross-sectional view of the elements of FIG. 6 with references to enlarged views, in accordance with some embodiments of the present invention;

FIG. 9 shows an enlarged cross-sectional view of the elements of FIG. 8, taken from dotted line 820, in accordance with some embodiments of the present invention;

FIG. 10 shows a cross-sectional view of an illustrative ESD, in accordance with some embodiments of the present invention;

FIG. 11 shows a cross-sectional view of the ESD of FIG. 10 undergoing an illustrative kinetic response, in accordance with some embodiments of the present invention;

FIG. 12 shows an illustrative diagram of an ESD coupled to an indication device, in accordance with some embodiments of the present invention;

FIG. 13 shows an illustrative diagram of an ESD coupled to an indication device and a control system, in accordance with some embodiments of the present invention;

FIG. 14 shows an illustrative ESD coupled to an indication device, in accordance with some embodiments of the present invention;

FIG. 15 shows a cross-sectional view of an illustrative ESD including a pressure tap, in accordance with some embodiments of the present invention;

FIG. 16 shows an enlarged cross-sectional view of the elements of FIG. 15, taken from dotted line 1520, in accordance with some embodiments of the present invention;

FIG. 17 shows an illustrative ESD coupled to an indication device, in accordance with some embodiments of the present invention;

FIG. 18 is a flow diagram of illustrative steps for indicating a kinetic response, in accordance with some embodiments of the present invention;

FIG. 19 is a flow diagram of illustrative steps for determining charge information, in accordance with some embodiments of the present invention;

FIG. 20 is a flow diagram of illustrative steps for controlling an ESD using an indication device, in accordance with some embodiments of the present invention;

FIG. 21 is a flow diagram of illustrative steps for controlling an ESD using more than one indicator, in accordance with some embodiments of the present invention;

FIG. 22 is a flow diagram of illustrative steps for calibrating an indication device, in accordance with some embodiments of the present invention; and

FIG. 23 is a graph of illustrative data showing temporal traces of cell voltage and kinetic response, in accordance with some embodiments of the present invention.

### DETAILED DESCRIPTION OF THE INVENTION

The present invention provides methods, arrangements, and apparatuses for determining charge information for an energy storage device (ESD).

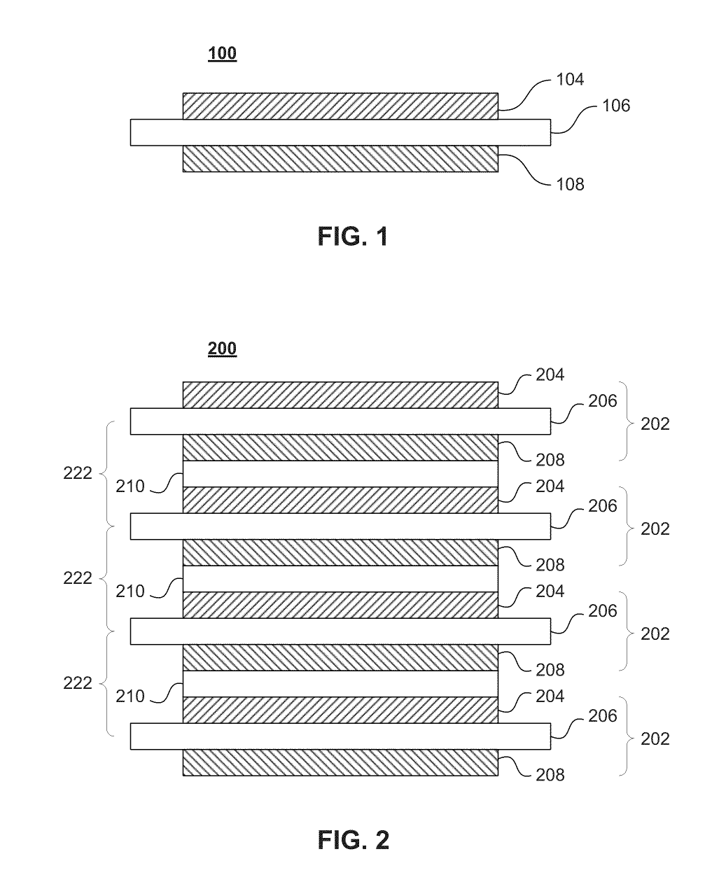

The invention will be described in the context of FIGS. 1-23, which show illustrative embodiments.

FIG. 1 shows a schematic cross-sectional view of an illustrative structure of bipolar unit (BPU) 100 in accordance with some embodiments of the present invention. Exemplary BPU 100 may include a positive active material electrode layer 104, an electronically conductive, impermeable substrate 106, and a negative active material electrode layer 108. Positive electrode layer 104 and negative electrode layer 108 are provided on opposite sides of substrate 106.

FIG. 2 shows a schematic cross-sectional view of an illustrative structure of stack 200 of BPUs 100 of FIG. 1 in accordance with some embodiments of the present invention. Multiple BPUs 202 may be arranged into stack 200. Within stack 200, electrolyte layer 210 is provided between two adjacent BPUs, such that positive electrode layer 204 of one BPU is opposed to negative electrode layer 208 of an adjacent BPU, with electrolyte layer 210 positioned between the BPUs. A separator (not shown) may be provided in one or more electrolyte layers 210 to electrically separate opposing positive and negative electrode layers. The separator allows ionic transfer between the adjacent electrode units for recombination, but may substantially prevent electronic transfer between the adjacent electrode units. As defined herein, a “cell” or “cell segment” 222 refers to the components included in substrate 206 and positive electrode layer 204 of a first BPU 202, negative electrode layer 208 and substrate 206 of a second BPU 202 adjacent to the first BPU 202, and electrolyte layer 210 between the first and second BPUs 202. Each impermeable substrate 206 of each cell segment 222 may be shared by applicable adjacent cell segment 222.

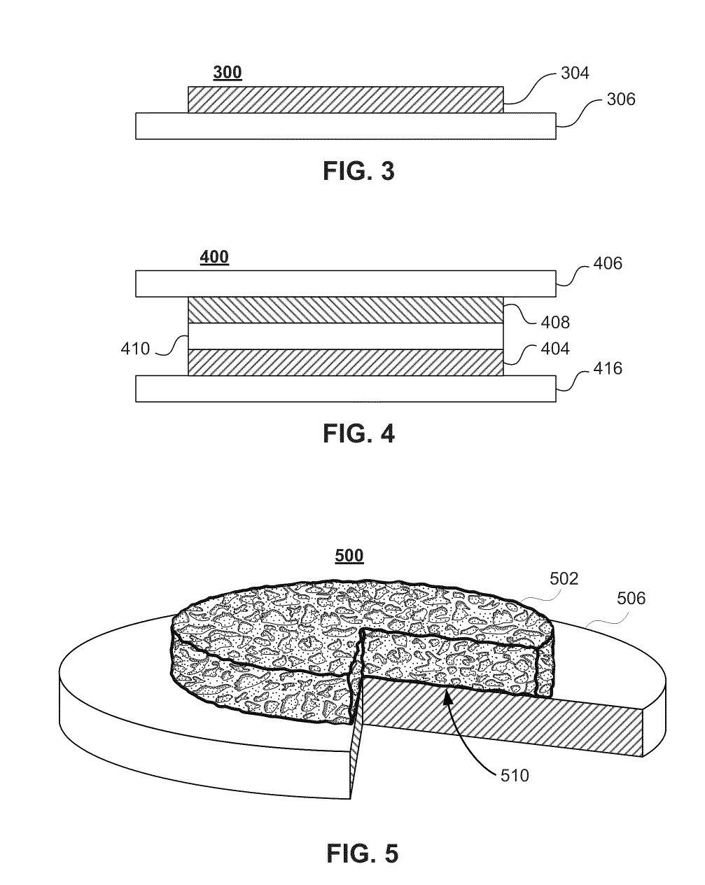

FIG. 3 shows a schematic cross-sectional view of an illustrative structure of mono polar unit (MPU) 300 in accordance with some embodiments of the present invention. Exemplary MPU 300 may include active material electrode layer 304 and electronically conductive, impermeable substrate 306. Active material layer 304 may be any suitable positive or negative active material.

FIG. 4 shows a schematic cross-sectional view of an illustrative structure of a device containing two MPUs of FIG. 3 in accordance with some embodiments of the present invention. Two MPUs 300 having a positive and a negative active material, respectively, may be stacked to form electrochemical device 400. Electrolyte layer 410 may be provided between two MPUs 300, such that positive electrode layer 404 of one MPU 300 is opposed to negative electrode layer 408 of the other MPU 300, with electrolyte layer 410 positioned between the MPUs. A separator (not shown) may be provided in electrolyte layer 410 to electrically separate opposing positive and negative electrode layers. In some embodiments two MPUs having a positive and negative active material, respectively, may be added to stack 200, along with suitable layers of electrolyte, to form a bipolar battery. Bipolar batteries and battery stacks are discussed in more detail in Ogg et al. U.S. Pat. No. 7,794,877, Ogg et al. U.S. patent application Ser. No. 12/069,793, and West et al. U.S. patent application Ser. No. 12/258,854, all of which are hereby incorporated by reference herein in their entireties.

The substrates used to form electrode units (e.g., substrate 106, 206, 406, 416) may be formed of any suitable electronically conductive and impermeable or substantially impermeable material, including, but not limited to, a non-perforated metal foil, aluminum foil, stainless steel foil, cladding material including nickel and aluminum, cladding material including copper and aluminum, nickel plated steel, nickel plated copper, nickel plated aluminum, gold, silver, any other suitable electronically conductive and impermeable material or any suitable combinations thereof. In some embodiments, substrates may be formed of one or more suitable metals or combination of metals (e.g., alloys, solid solutions, plated metals). Each substrate may be made of two or more sheets of metal foils adhered to one another, in certain embodiments. The substrate of each BPU may typically be between 0.025 and 5 millimeters thick, while the substrate of each MPU may be between 0.025 and 30 millimeters thick and act as terminals or sub-terminals to the ESD, for example. Metalized foam, for example, may be combined with any suitable substrate material in a flat metal film or foil, for example, such that resistance between active materials of a cell segment may be reduced by expanding the conductive matrix throughout the electrode.

The positive electrode layers provided on the substrates to form the electrode units of the invention (e.g., positive electrode layers 104, 204 and 404) may be formed of any suitable active material, including, but not limited to, nickel hydroxide (Ni(OH)₂), nickel oxyhydroxide (NiOOH), zinc (Zn), lithium iron phosphate (LiFePO₄), lithium manganese phosphate (LiMnPO₄), lithium cobalt oxide (LiCoO₂), lithium manganese oxide (LiMnO₂), any other suitable material, or combinations thereof, for example. The positive active material may be sintered and impregnated, coated with an aqueous binder and pressed, coated with an organic binder and pressed, or contained by any other suitable technique for containing the positive active material with other supporting chemicals in a conductive matrix. The positive electrode layer of the electrode unit may have particles, including, but not limited to, metal hydride (MH), palladium (Pd), silver (Ag), any other suitable material, or combinations thereof, infused in its matrix to reduce swelling, for example. This may increase cycle life, improve recombination, and reduce pressure within the cell segment, for example. These particles, such as MH particles, may also be in a bonding of the active material paste, such as Ni(OH)₂, to improve the electrical conductivity within the electrode and to support recombination.

The negative electrode layers provided on the substrates to form the electrode units of the invention (e.g., negative electrode layers 108, 208, and 408) may be formed of any suitable active material, including, but not limited to, MH, cadmium (Cd), manganese (Mn), Ag, carbon, silicon, any other suitable material, or combinations thereof, for example. The negative active material may be sintered, coated with a suitable binder (e.g., aqueous, non-aqueous, organic, inorganic) and pressed, or contained by any other suitable technique for containing the negative active material with other supporting chemicals in a conductive matrix, for example. The negative electrode side may have chemicals including, but not limited to, Ni, Zn, Al, any other suitable material, or combinations thereof, infused within the negative electrode material matrix to stabilize the structure, reduce oxidation, and extend cycle life, for example.

Various suitable binders, including, but not limited to, organic carboxymethylcellulose (CMC), Creyton rubber, PTFE (Teflon), polyvinylidene fluoride (PVDF), polyvinyl alcohol (PVA), any other suitable organic or inorganic material or, any suitable combinations thereof, for example, may be mixed with or otherwise introduced to the active material to maintain contact between the active material and a substrate, solid-phase foam, any other suitable component, or any suitable combination thereof. Any suitable binders may be included in slurries or any other mixtures to increase adherence, cohesion or other suitable property or combination thereof. In some embodiments, n-methyl-2-pyrrolidone (NMP) may be used as liquid agent (e.g., a solvent) in slurries.

The separator of each electrolyte layer of an ESD may be formed of any suitable material that electrically isolates its two adjacent electrode units while allowing molecular and ionic transfer between those electrode units. The separator may contain cellulose super absorbers to improve filling and act as an electrolyte reservoir to increase cycle life, wherein the separator may be made of a polyabsorb diaper material, for example. The separator may, thereby, release previously absorbed electrolyte when charge is applied to the ESD. In certain embodiments, the separator may be of a lower density and thicker than normal cells so that the inter-electrode spacing (IES) may start higher than normal and be continually reduced to maintain the capacity (or C-rate) of the ESD over its life as well as to extend the life of the ESD.

The separator may be a relatively thin material bonded to the surface of the active material on the electrode units to reduce shorting and improve recombination. This separator material may be sprayed on, coated on, pressed on, or combinations thereof, for example. The separator may have a recombination agent attached thereto. This agent may be infused within the structure of the separator (e.g., this may be done by physically trapping the agent in a wet process using a polyvinyl alcohol (PVA or PVOH) to bind the agent to the separator fibers, or the agent may be put therein by electro-deposition), or it may be layered on the surface by vapor deposition, for example. The separator may be made of any suitable material such as, for example, polypropylene, polyethylene, any other suitable material or any combinations thereof. The separator may include an agent that effectively supports recombination, including, but not limited to, lead (Pb), Ag, platinum (Pt), Pd, any other suitable material, or any suitable combinations thereof, for example. In some embodiments, an agent may be substantially insulated from (e.g., not contact) any electronically conductive component or material. For example, the agent may be positioned between sheets of the separator material such that the agent does not contact electronically conductive electrodes or substrates. While the separator may present a resistance if the substrates of a cell move toward each other, a separator may not be provided in certain embodiments of the invention that may utilize substrates stiff enough not to deflect.

The electrolyte of each electrolyte layer of an ESD may be formed of any suitable chemical compound that may ionize when dissolved or molten to produce an electrically conductive medium. The electrolyte may be a standard electrolyte of any suitable ESD, including, but not limited to, NiMH and lithium-ion ESDs, for example. The electrolyte in a lithium-ion based ESD may include, for example, ethylene carbonate (C₃H₄O₃), diethyl carbonate (C₅H₁₀O₃), lithium hexafluorophosphate (LiPF₆), any other suitable lithium salt, any other organic solvent, any other suitable material or any suitable combination thereof. The electrolyte in a NiMH based ESD may be, for example, an aqueous solution. The electrolyte may contain additional suitable materials, including, but not limited to, lithium hydroxide (LiOH), sodium hydroxide (NaOH), calcium hydroxide (CaOH), potassium hydroxide (KOH), any other suitable metal hydroxide, any other suitable material, or combinations thereof, for example. The electrolyte may also contain additives to improve recombination, including, but not limited to Pt, Pd, any suitable metal oxides (e.g., Ag₂O), any other suitable additives, or any combinations thereof, for example. The electrolyte may also contain rubidium hydroxide (RbOH), or any other suitable material, for example, to improve low temperature performance. The electrolyte may be frozen within the separator and then thawed after the ESD is completely assembled. This may allow for particularly viscous electrolytes to be inserted into the electrode unit stack of the ESD before the gaskets have formed substantially fluid tight seals with the electrode units adjacent thereto.

Electrodes may contain an electronically conductive network or component. The electronically conductive network or component may reduce ohmic resistance and may allow increased interface area for electrochemical interactions. For example, in stack 400 shown in FIG. 4, the interface between electrolyte 410 and either positive electrode layer 404 or negative electrode layer 408 appears to be a planar, two dimensional surface. While a planar or substantially planar interface may be employed in some embodiments of energy storage devices, the electrode may also have porous structure. The porous structure may increase the interface area between electrode and electrolyte, which may increase the achievable charge or discharge rate. Active materials may be mixed with or applied to the conductive component or network to extend the interface over a greater surface area. Electrochemical interactions may occur at the interface between an active material, an electrolyte, and an electronically conductive material.

The electronically conductive substrate of an ESD may be impermeable or substantially impermeable, thereby preventing leakage or short circuiting. In some arrangements, one or more porous electrodes may be maintained in contact with a substrate, as shown in FIGS. 1-4. This arrangement may allow for electronic transfer among an external circuit and the electrode.

FIG. 5 shows illustrative electrode structure 500 with a cutaway section in accordance with some embodiments of the present invention. Electrode structure 500 may include electrode 502 and substrate 506 that may share interface 510 as a plane of contact. Interface 510 represents the plane or path in space where at least two components, materials or suitable combination thereof meet in contact. The term “interface” as used herein describes the substantially planar area of contact between any two suitable components, or any other plane of contact between two distinct materials or components. Although shown as a planar disk geometry, electrode structure 500 may have any suitable shape, curvature, thickness (of either layer), relative size (among substrate and electrode), relative thickness (among substrate and electrode), any other property or any suitable combination thereof. Electrode 502 may include one or more electronically conductive components (e.g., metals), one or more active materials (e.g., Ni(OH)₂), one or more binders, one or more nanostructured materials, any other suitable materials or any combination thereof.

Active materials of an ESD may undergo volumetric expansion or contraction as a result of electrical activity such as charging or discharging, which may cause a change in the state of charge of the ESD. In some embodiments, active materials may undergo alternating volumetric expansions and contractions in response to charging and discharging events. Volumetric change may result from material phase transitions, formation reactions, insertion reactions, intercalation of atoms or molecules within layer of an active material, other physical or chemical processes, or any suitable combinations thereof. Some ESD components such as, for example, substrates, monopolar plates, or other components, may not undergo substantial volumetric change at a time when an active material may undergo volumetric change. In some embodiments, an ESD may allow expansion, contraction, or both, of one or more components relative to one or more other components to reduce, increase, maintain or otherwise manage the volume of a portion (e.g., a suitable collection of components) of the ESD. In some embodiments, a volumetric change may occur substantially along one direction (e.g., an axial stacking direction) and may, for example, be designated a “linear displacement.”

In some embodiments, pressures within cells of an ESD may change as charge or discharge processes are applied. For example, pressure may be changed by a volumetric change in one or more active materials within a cell. In a further example, pressure may change as molecules are added to or removed from the gas phase within a cell. In some embodiments, an ESD may allow expansion, contraction, or both, of one or more components relative to one or more other components to reduce, increase, maintain or otherwise manage the pressure within one or more cells. Variable volume containment for ESDs is discussed in more detail in West et al. U.S. patent application Ser. No. 12/694,638, which is hereby incorporated by reference herein in its entirety.

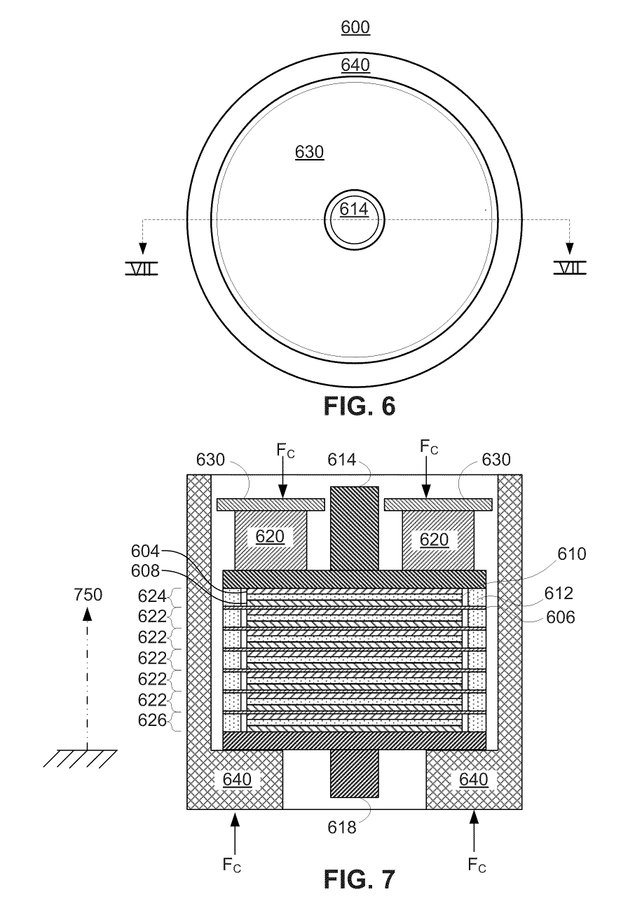

Shown in FIGS. 6 and 7 are a top plan view and a cross-sectional view, respectively, of an illustrative ESD 600 in accordance with some embodiments of the present invention. As shown in FIG. 7, for example, ESD 600 includes cells 622 having one or more bipolar plates 606, a positive active material layer 604, a negative active material layer 608, an electrolyte layer 610, and one or more gaskets 612. ESD 600 may also include cells 624 and 626, which may include, for example, positive monopolar plate 614 or negative monopolar plate 618, respectively, positive active material layer 604, negative active material layer 608, electrolyte layer 610, gaskets 612, and one or more bipolar plates 606.

In some embodiments, ESD 600 may be a bipolar battery, in which cells are stacked in series, parallel, or any suitable configuration of series and parallel stacking. Energy storage devices having cells electrically coupled in series and in parallel are discussed in more detail in West et al. U.S. patent application Ser. No. 12/766,225, which is hereby incorporated by reference herein in its entirety. Vector 750 of FIG. 7 shows a direction of stacking. It will be understood that cells may be stacked in any suitable direction or orientation in accordance with the present invention. In some embodiments, stacks of non-bipolar ESDs (e.g., stack 400 of FIG. 4) may be included in ESD 600. In some arrangements, adjacent non-bipolar ESDs may be separated or otherwise insulated from each other by a suitable gap or material layer. Any suitable number of cells, of any suitable type or combination of types, may be included in ESD 600. For example, in some embodiments, a single cell may be included in ESD 600. In a further example, in some embodiments, ESD 600 may include one or more cells that may have different chemistries relative to one another. For example, a first cell may include Li-ion based components, and a second cell may include NiMH based components.

In some embodiments, one or more gaskets 612 may be included in ESD 600. Gaskets 612 may be used to, for example, seal individual cells, allow for substantially leak-free expansion/contraction (e.g., dynamic seals), align one or more components (e.g., BPUs), cushion impact, provide electronic or ionic insulation, perform any other suitable function, or any combinations thereof. In some embodiments, gaskets 612 may contain void space. For example, void space within a gasket may aid in deformation (e.g., stretching, contracting) of the gasket during expansion/contraction of ESD 600. In some embodiments, gaskets 612 may be, for example, elastic, flexible, compressible, rigid, any other mechanical designation, or any suitable combinations thereof. Gaskets 612 may include bolts holes, grooves, relief features, o-rings, sealants, any other suitable material, component, or feature, or any suitable combinations thereof. In some embodiments, for example, multiple cells may be suitably bonded to adjacent cells using any suitable sealant (e.g., silicone sealant), adhesive, or other compound.

As shown in FIGS. 6 and 7, any suitable structural components or combinations thereof which may provide rigidity, alignment, containment, compression, mounting, impact dampening, or any other structural function may be included in ESD 600. For example, ESD 600 may include spring 620, compression plate 630, and container 640.

Container 640 may be used to, for example, contain leaks, contain venting fluids, provide insulation (e.g., electrical, ionic, thermal) between ESD 600 and the immediate surroundings, impart compressive force to the cells of ESD 600, provide structural mounting features, provide any other suitable function, or any suitable combinations thereof. Spring 620 and compression plate 630 may be used, for example, to impart compressive force to energy storage device. In some embodiments, for example, leaking, component alignment shifting, or other system altering processes may be reduced or substantially reduced by application of suitable compressive forces. Compressive force “F_{c}”, as shown in FIG. 7, may be applied to compression plate 630 from, for example, external mountings, spring 620, container 640, or bolts extending through compression plate 630 to container 640. An equal and opposite force, relative to force “F_{c}”, may also be applied, for example, to container 640 (e.g., a normal force from mounting of container 640). For example, in some embodiments, threaded bolts extending through holes in compression plate 630 and spring 620 to suitable internal threads in container 640, on any suitable bolt circle or pattern, may be tightened to provide suitable compressive forces to ESD 600. In some embodiments, compression plate 630 and container 640 may be spatially fixed relative to one another, while spring 620 may undergo contraction or expansion along the direction of vector 750 or any other suitable direction (e.g., radially). Any suitable assembly technique may be used to maintain the arrangement of ESD 600.

In some embodiments, ESD 600 may be constrained to prevent or reduce displacement during charging and discharging. Constraining displacement of ESD 600 may, in some embodiments, cause increased cell gas pressures, compressive forces, any other kinetic response, or any combination thereof, to exist relative to an unconstrained energy storage device. In some embodiments, a compressive force arising from component weights in a stacking configuration may aid in maintaining the assembly of ESD 600.

During operation, which may include charging, discharging, or both, ESD 600 may undergo kinetic responses such as, for example, expansion (e.g., along the direction of vector 750 or other direction), contraction (e.g., along the direction of vector 750 or other direction), other displacement modes in any suitable direction, pressure changes within one or more cells, force changes on one or more components, any other suitable kinetic response, or any suitable combinations thereof. For example, spring 620 may contract or expand along the direction of vector 750 as cells 622, 624 and 626 expand or contract along the direction of vector 750, respectively.

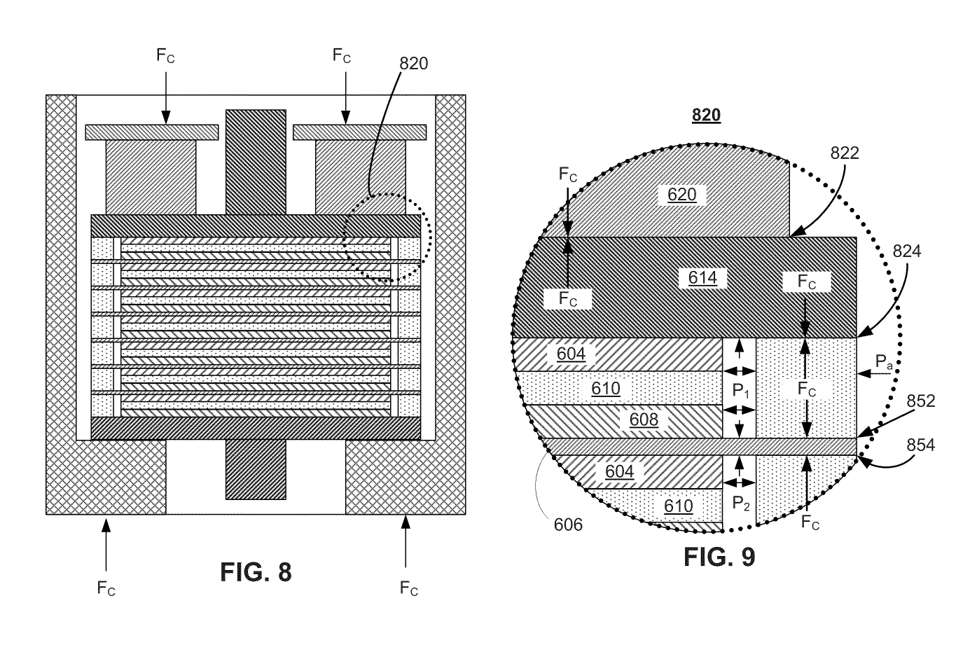

FIG. 8 shows a cross-sectional view of the elements of FIG. 6 with dotted line 820 referencing an enlarged view, in accordance with some embodiments of the present invention.

Shown in FIG. 9 is a partial cross sectional view taken from dotted line 820 of FIG. 8, including portions of cell 624, one of cells 622, positive monopolar plate 614 and spring 620. During charging and discharging processes, pressure “P₁” in cell 624, pressure “P₂” in cell 622, or pressure from any other cell in the stack, or any combination thereof, may change as a result of chemical processes, electrochemical processes, or both, which may occur as a result of electrical activity. The pressure in each cell of a stack may change independently or in concert with the pressure in other cells in response to electrical activity. For example, in some embodiments, during charging and discharging processes, gas phase materials (e.g., diatomic hydrogen, diatomic oxygen) may be formed which may increase cell pressure. In some embodiments, expansion and contraction of solid phase active materials may cause an increase or decrease in gas pressure within one or more cells in a stack. In some embodiments, one or more cells in a stack may be coupled pneumatically or hydraulically, which may allow for gas or liquid transfer, respectively, and pressure equilibration amongst suitably coupled cells.

Compressive forces “F_{c}” may act on any suitable components of ESD 600. For example, in some embodiments, an equal and opposite force “F_{c}” may act at component interfaces such as, for example, interfaces 822, 824, 852, 854, any other suitable interface, or any combination of interfaces. Compressive forces may be distributed across an interface in any suitable manner, in accordance with the actual contact area. At a particular interface between components, of which none are substantially accelerating relative to a fixed frame, equal and opposite forces will be present on the components. For example, if a compressive force “F_{c}” is applied as shown in FIG. 8, there may exist equal and opposite forces “F_{c}” acting on adjacent components at the interface between the components as shown in FIG. 9.

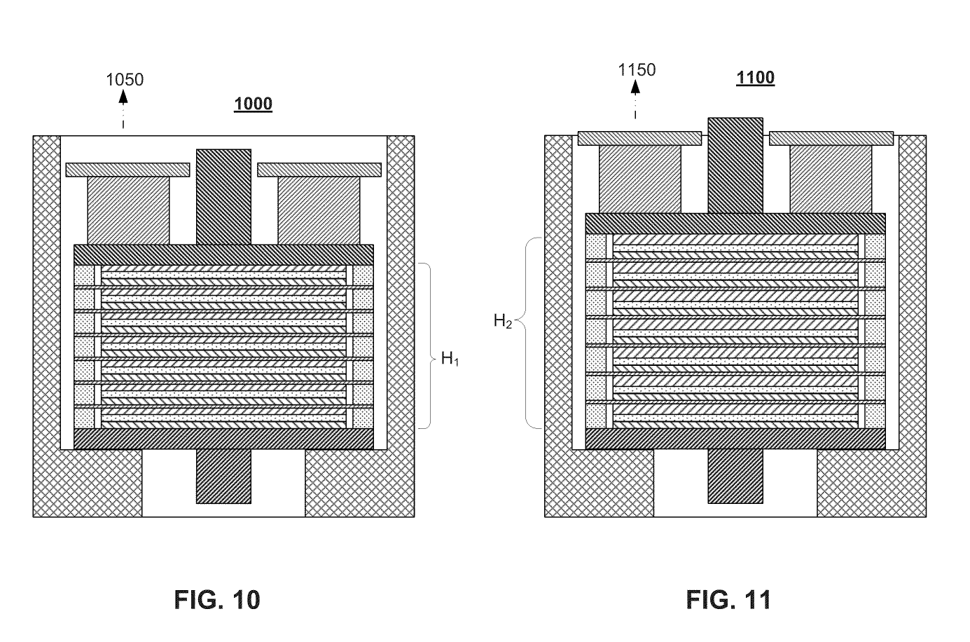

Shown in FIG. 10 is a cross-sectional view of illustrative ESD 1000, in accordance with some embodiments of the present invention. ESD 1000 may have one or more characteristics such as a compression force, stack height “H₁”, cell gas pressure, or any other suitable characteristics. The term “characteristic” as used herein shall refer to any physical property (e.g., mechanical, electrical, chemical) associated with an ESD that may partially or wholly describe the ESD.

Shown in FIG. 11 is a cross-sectional view of ESD 1100, in accordance with some embodiments of the present invention. Energy storage device 1100 of FIG. 11 may have different characteristics relative to ESD 1000 of FIG. 10. For example, in some embodiments, during charging or discharging processes, ESD 1100 may correspond to an expansion of ESD 1000 in the direction of vector 1050. Expansion may, for example, cause an increase in ESD stack height from “H₁” to “H₂”, as shown by FIGS. 10 and 11, respectively. In some embodiments, gaskets 612 may expand, contract or otherwise deform to maintain or substantially maintain a seal on corresponding cells during expansion and contraction.

During electrical activity (e.g., charging or discharging) of an ESD, one or more characteristics of the ESD (e.g., ESD 1000, ESD 1100) may change. In some embodiments, state of charge or robustness of an ESD may be indicated by characteristics such as displacement, compression force, cell gas pressure, cell voltage, any other suitable characteristic, any suitable change in characteristic, or any suitable combination thereof. The term “charge information” as used herein shall refer to the collective values or changes in values of the state of charge of an ESD, robustness of an ESD, any other suitable information regarding an ESD, or combinations thereof. In some embodiments, charge information of an ESD may also include one or more characteristics of an ESD.

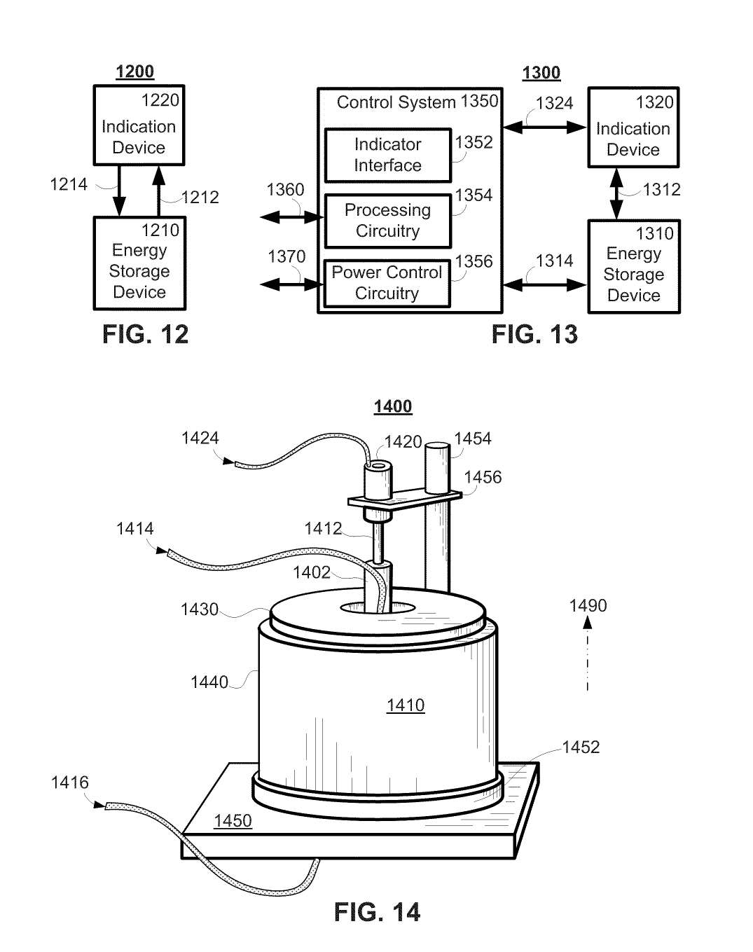

Shown in FIG. 12 is a diagram of illustrative system 1200 which may include ESD 1210 and indication device 1220, in accordance with some embodiments of the present invention. ESD 1210 may be any suitable type of ESD, bipolar or otherwise, including, for example, an NiMH type battery, a lithium-ion type battery, a lead acid type battery, any other suitable type of ESD, or any suitable combination thereof.

Indication device 1220 may be any suitable device or system which may indicate a kinetic response including, for example, a force transducer, a pressure transducer, a displacement sensor, an optical device (e.g., photon source and detector, imaging device), a visual indicator, a proximity sensor (e.g., infrared, capacitive, inductive proximity sensors), a Hall effect sensor, a voltmeter (e.g., digital volt meter), an ammeter, an ohmmeter, an electrochemical impedance spectroscopy system, any other suitable indication device or system, or any combination thereof. Kinetic responses may arise from electrical activity of ESD 1210. An indication of a kinetic response of an ESD is not limited to a value or a quantitative indicator, and may represent a trend, change (e.g., increase, decrease), or other qualitative indicator of a kinetic response.

ESD 1210 may be coupled to indication device 1220 by couplings 1212 and 1214. Couplings 1212 and 1214 may include, for example, electrical coupling (e.g., electrical wires), direct contact (e.g., force transducer in contact with ESD 1210), optical coupling (e.g., reflection, absorption of photons from a suitable source), any other suitable arrangement for coupling ESD 1210 to indication device 1220, or any suitable combinations thereof. In some embodiments, for example, coupling 1212 may allow for a kinetic response of ESD 1210 to be detected by (e.g., imaged by), or directly interact with (e.g., provide force to, cause displacement to) indication device 1220. In some embodiments, for example, indication device 1220 may provide via coupling 1214 a suitable stimulus, perturbation, any other optical, electrical, or mechanical reference signal, or any combination of signals which may indicate a kinetic response of ESD 1210. Couplings 1212 and 1214 may be suitably combined or otherwise used in concert in some embodiments, for example, by using various signal processing techniques such as modulating/demodulating or multiplexing/de-multiplexing. In some embodiments (not shown), coupling 1214 may be omitted.

In some embodiments, one or more pressure sensors (e.g., piezoelectric, piezoresistive, capacitive) may be coupled to one or more cells (e.g., cells 622 of FIG. 6) of an ESD via suitable pneumatic or hydraulic conduits (e.g., tubes, fittings). Pressure sensors may receive a power signal (e.g., DC voltage and current, AC voltage and current) from an external power source or supply, and may respond to or otherwise indicate (e.g., DC signal, AC signal) pressures or pressure changes in one or more cells of ESD 1210. In some embodiments, a pressure sensor may include mechanical components such as, for example, a spring, diaphragm, piston, any other suitable mechanical components, or any combination thereof. Any suitable type of pressure sensor may be used to indicate relative (e.g., gage), absolute, or differential pressure, or any suitable combinations thereof.

In some embodiments, one or more displacement sensors may be coupled to one or more components of an ESD (e.g., ESD 1210 of FIG. 12) via direct contact. The one or more displacement sensors may receive a power signal (e.g., DC voltage and current, AC voltage and current) from an external power source or supply, and may respond to or otherwise detect and indicate (e.g., DC signal, AC signal) displacements or displacement changes of one or more components of ESD 1210. Any suitable type of displacement sensor may be used to indicate relative, absolute, or differential displacement, or any suitable combinations thereof, of one or more components of ESD 1210.

In some embodiments, one or more force sensors (e.g., piezoelectric, piezoresistive, capacitive) may be coupled to one or more components of an ESD (e.g., energy storage device 1210 of FIG. 12) via direct contact, for example. The one or more force sensors may receive a power signal (e.g., DC voltage and current, AC voltage and current) from an external power source or supply, and may respond to or otherwise detect and indicate (e.g., DC signal, AC signal) forces or changes in force acting on one or more components of ESD 1210. Any suitable type of force sensor may be used to indicate relative, absolute, or differential force, or any suitable combinations thereof. In some embodiments, a force sensor may include mechanical components such as, for example, a spring, diaphragm, piston, any other suitable mechanical components, or any combination thereof.

In some embodiments, one or more optical sensors (e.g., interferometric, intensity-based, image-based) may be coupled to one or more components of an ESD (e.g., ESD 1210 of FIG. 12) via any suitable optical path, for example. The one or more optical sensors or detectors may receive a power signal (e.g., DC voltage and current, AC voltage and current) from an external power source or supply, and may respond to or otherwise detect and indicate (e.g., DC signal, AC signal) optical phenomena. Optical phenomena may include absorption, transmission, reflection, imaging, any other optical, photonic or imaging processes, or any suitable combinations thereof. Any suitable type of optical sensor may be used to indicate any suitable kinetic responses, or any suitable combinations thereof. In some embodiments, a photonic source may be used to provide photons of any suitable intensity, energy distribution, coherence, any other suitable property, or any combinations thereof, which may be configured to indicate a kinetic response of ESD 1210. For example, in some embodiments, a laser may be used to provide a photonic source, which may be reflected from one or more surfaces of ESD 1210, and detected by one or more photonic detectors (e.g., photomultiplier tubes, charged coupled device (CCD) camera) which may indicate changes in one or more ESD characteristics. In a further example, an imaging camera may monitor the relative position of one or more components, surfaces, edges, demarcations (e.g., indentations, holes, raised features), or any other suitable ESD surface features which may change as ESD characteristics change. Differences in the output (e.g., video frames, images) of the imaging camera may indicate one or more kinetic responses (e.g., displacement) of the ESD. In some embodiments, pattern matching techniques, feature detection techniques, other image processing techniques, or combinations thereof, may be used to determine a kinetic response from an imaging indication device.

In some embodiments, more than one indication device may be coupled to an ESD. For example, in some embodiments, axial displacement and stack voltage of a bipolar ESD may be monitored using a displacement sensor and digital voltmeter, respectively, which may be coupled to the bipolar ESD. Any other combination having any suitable number of indication devices may be coupled to ESD 1210 in accordance with the present invention.

In some embodiments, a user may observe a change in one or more characteristics based at least in part on the output of the indication device. For example, indication device 1220 may include a demarcated surface (e.g., a ruler) in close visual proximity to ESD 1210. Changes in one or more spatial characteristics may be indicated by a relative change in position between at least one feature of ESD 1210 and at least one demarcation on a demarcated surface of indication device 1220. In a further example, in some embodiments, a user may monitor the output of an imaging indication device for a kinetic response of ESD 1210.

Shown in FIG. 13 is a diagram of illustrative system 1300 which may include ESD 1310, indication device 1320, and control system 1350, in accordance with some embodiments of the present invention. ESD 1310 may be any suitable type of ESD (e.g., energy storage device 1210 of FIG. 12) or combinations of ESDs. Indication device 1320 may be any suitable device which may indicate a kinetic response (e.g., indication device 1220 of FIG. 12). Coupling 1312 may include any suitable type of coupling (e.g., couplings 1212 and 1214 of FIG. 12) between energy storage device 1310 and indication device 1320.

As shown in FIG. 13, for example, control system 1350 may include indicator interface 1352, processing circuitry 1354, and power control circuitry 1356. In some embodiments, some or all components of control system 1350 may be local to ESD 1310 or indicator device 1320 such as, for example, a local CPU or onboard processing unit. In some embodiments, some or all components of control system 1350 may be located remote from energy storage device 1310 and indicator device 1320 such as, for example, a remote application server or remote processing facility. Control system 1350 may be used to control or otherwise interact with any suitable device, system, network, or suitable combinations thereof such as, for example, electric vehicles, remote power facilities (e.g., solar panel array, wind turbine), or an electric transmission grid.

Indicator interface 1352 may include a data interface for wired (e.g., local area networks, control leads) or wireless (e.g., WiFi, optical) communication with one or more indication devices. Indicator interface 1352 may, via coupling 1324, supply signals (e.g., power signals, reference signals) to indication device 1320, receive signals (e.g., modulated signals, kinetic response indication signals) from indication device 1320, or both. In some embodiments, indicator interface 1352 may include, for example, an RCA type interface connection, S-video interface connection, any other suitable video or imaging interface, or any combinations thereof.

In some embodiments, indicator interface 1352, coupling 1324, or both, may include, for example, a wire bundle including one or more insulated wires, electrical conduits, terminal blocks, plug-in wire connectors (e.g., Molex® type connectors), sealed wire assemblies (e.g., Conax® type sealed fittings), signal conditioning components (e.g., band pass filters, amplifiers, rectifiers, bridges, multiplexers, de-multiplexers, fuses, diodes), any other suitable electrical components, or any suitable combination thereof. For example, indication device 1320 may be a strain gage attached to suitable components of ESD 1310. Indicator interface 1352, coupling 1324, or both, may include a four-leg Wheatstone bridge circuit wherein the strain gage is one of the four resistive elements of the bridge. The bridge circuit may be electrically coupled to indication device 1320 with insulated lead wires and electrical terminals. Changes in the resistance of the strain gage, due to displacement of ESD 1310 (e.g., arising from electrical activity), may cause imbalance in the Wheatstone bridge circuit and provide an indication of the kinetic response (i.e., displacement) of ESD 1310.

In some embodiments, indicator interface 1352, coupling 1324, or both, may include, for example, fluid (e.g., gas, liquid) conduits, tube fittings, pipe fittings, pressure regulators, pressure gages, flow switches, valves (e.g., check valves, needle valves), any other suitable pneumatic or hydraulic components, or any suitable components thereof. For example, in some embodiments, indication device 320 may be a differential pressure transducer which may indicate the pressure difference between a first and second pressure ports (e.g., high and low pressure ports). One of the pressure ports may be fluidly coupled to a reference port of indicator interface 1352, which may provide a reference pressure at the second pressure port. The fluid couple may include a length of tube and compression tube fittings to seal the tube to the ports. The first pressure port of indication device 1320 may be fluidly coupled to one cell of an ESD (e.g., ESD 1310).

In some embodiments, indicator interface 1352, coupling 1324, or both, may include, for example, fiber optics, optical components (e.g., lenses, mirrors, spectral filters, intensity filters, beam-splitters, slits), a beam stop, a photonic power meter, any other suitable optical components, or any suitable combinations thereof. For example, indication device 1320 may include a sensor which communicates with indicator interface 1352 via coupling 1324 which may be a fiber optic cable. Coupling 1324, indicator interface 1352, or both, may include, for example, mechanical transfer (MT) fiber optic connectors coupled to a fiber optic cable.

Processing circuitry 1354 may include one or more central processing units, microprocessors, collection of processors (e.g., parallel processors), CPU cache, random access memory (RAM), memory hardware (e.g., hard disk), I/O communications interfaces, suitable circuitry, any other hardware components, any suitable software, or suitable combinations thereof. Processing circuitry 1354 may include any suitable input-output (I/O) interface for data communication with, for example, wired (e.g., local area networks, control leads) or wireless (e.g., WiFi, optical fiber) communication networks, local or remote databases (e.g., data servers) one or more energy storage devices, any other suitable networks or devices, or any combinations thereof. Processing circuitry 1354 may, in some embodiments, include signal processing components such as, for example, a filter (e.g., band pass filters), analog to digital (AD) converter, digital to analog (DA) converter, modulator, demodulator, amplifier (e.g., operational amplifier) any other suitable signal processing equipment, or any combinations thereof. In some embodiments, processing circuitry 1354 may execute software commands (e.g., closed loop control commands).

In some embodiments, processing circuitry 1354 may send and receive signals via data coupling 1360, which may be further coupled to a network, database, processing facility, any other suitable network, device or facility, or any combination thereof, located locally or remotely. In some embodiments, data coupling 1360 may not be included in control system 1350 (e.g., a stand-alone system). Data coupling 1360 may include wire leads (e.g., insulated wires, ribbon cables), terminal strips, metal clamps, screw down terminals, soldered connections, universal serial bus (USB) connections, plug in ethernet connections, optical couplings (e.g., optical fiber couplings, infrared signals), any other suitable components, materials, connectors, and assemblies, or any combination thereof.

In some embodiments, processing circuitry 1354 may include calibration information (e.g., calibration constants, correlation parameters, operating maps), databases, any other suitable information, or any combination thereof, stored in any suitable memory device or combination of memory devices. Memory devices may be located locally or remotely relative to processing circuitry 1354, which may use data coupling 1360 to send and receive data from suitable memory devices. Calibration information may be used to, for example, estimate the state of charge of ESD 1310 based on measured characteristics of the ESD, or any other information.

Processing circuitry 1354 may send and receive signals with indicator interface 1352. For example, in some embodiments, indicator interface 1352 may output to processing circuitry 1354 signals corresponding to a kinetic response of ESD 1310. Processing circuitry 1354 may, in some embodiments, determine timing schedules, current or voltage limits, current or voltage rate limits, alarms, any other electrical indicators, or any combinations thereof, that may describe charging and discharging of ESD 1310 based at least in part on a received signal from indicator interface 1352.

Processing circuitry 1354 may be coupled to power control circuitry 1356 via coupling 1314. Power control circuitry 1356 may be used to control electrical activity of ESD 1310. In some embodiments, power control circuitry 1356 may be used to monitor, control, regulate, or otherwise manage supplying and extracting electrical power from energy storage device 1310 via coupling 1314.

In some embodiments, power control circuitry 1356, coupling 1314, or both, may include, for example, wire leads, contactors, fuses, breakers, super-capacitors, switches, voltage regulators, current regulators, transformers, any other suitable electronic components, or any combination thereof. For example, in some embodiments, power control circuitry 1356 may include one or more super-capacitors which may be electrically coupled to energy storage device 1310 to provide fast response to electrical load changes. In a further example, fuses, breakers, or contactors may be used by power control circuitry 1356 to interrupt electrical current to or from energy storage device 1310 to prevent, for example, an over-current condition.

In some embodiments, power control circuitry 1356 may be coupled to a device, system, network, or combinations thereof, via power coupling 1370. For example, in some embodiments, power coupling 1370 may couple power control circuitry 1356 to a drive-train (e.g., electric vehicle (EV) drive-train, hybrid EV (HEV) drive-train, plug-in HEV drive-train), electric load (e.g., adjustable resistive load bank), electromechanical device (e.g., DC motor, DC solenoid, generator, wind turbine), electrochemical device (e.g., electrolyzer), photoelectrochemical device, photovoltaic device (e.g., solar cell), power transmission network, any other suitable power network, device, or system, or any combination thereof. It will be understood that in some embodiments, power coupling 1370 may not be included in control system 1350 (e.g., an ESD test stand). Power coupling 1370 may include wire leads (e.g., insulated wires, braided cables), electronically conductive members (e.g., metal railings), metal clamps, screw down terminals, soldered connections, any other suitable components, materials, and assemblies, or any combination thereof.

In some embodiments, any suitable feature or component of controls system 1350 may be included as a part of indication device 1320. For example, indication device 1320 may be included in a computer, which may integrate an indicator interface, processing circuitry and power control circuitry into a single device. The computer, which includes the indication device, may be coupled to ESD 1310 via couplings 1312, 1314, or both.

Shown in FIG. 14 is illustrative system 1400 including ESD 1410 coupled to indication device 1420, in accordance with some embodiments of the present invention. Indication device 1420 may be a linear displacement sensor, linear force sensor, any other suitable indication device which may indicate a kinetic response, or any combination thereof.

In some embodiments, compression plate 1430 may be bolted, pressed, or otherwise rigidly affixed to other components included in ESD 1410, such as, for example, wrapper 1440, or a spring. In some embodiments, compression plate 1430 may distribute a compressive force to one or more components of ESD 1410. Monopolar plate 1402 may, for example, be electrically coupled to power lead 1414. Power lead 1414 may, along with power lead 1416, couple ESD 1410 to an external power control circuit (e.g., power control circuitry 1356), external device (e.g., DC motor), external network, or any other suitable system or combination of systems. In some embodiments, power leads 1414 and 1416 may correspond substantially to coupling 1314 of FIG. 13. In some embodiments, power leads 1414 and 1416 may include screw down terminals, soldered connections, insulated wires, braided cables, metal rails, ribbon cables, grounding lugs, any other suitable components for transmitting electric power, or any combination thereof.

ESD 1410 of system 1400 may be in contact with or otherwise coupled to base 1450 of system 1400. As shown in FIG. 14, for example, base 1450 includes stand 1454, bracket 1456, and mounting coupling 1452 which may provide a mechanical datum for ESD 1410 and a suitable mounting for indication device 1420. Stand 1454, base 1450, bracket 1456, and mounting coupling 1452 may include, for example, some or all of a frame (e.g., vehicle frame), a ledge, a housing, any other structural components or arrangements, or any combination thereof. In some embodiments, more than one ESD may be in contact with stand 1454, base 1450, bracket 1456, or mounting coupling 1452. Stand 1454, base 1450, bracket 1456, and mounting coupling 1452 may be made of any suitable material such as, for example, metal, plastic, graphite, carbon fiber, fiberglass, any other suitable structural material, or any combination or composite thereof. In some embodiments, stand 1454, base 1450, bracket 1456, and mounting coupling 1452 may form a substantially rigid structure. Mounting coupling 1452 may be used, for example, to maintain the alignment, position, and/or orientation of ESD 1410 relative to other components (e.g., indication device 1420).

In some embodiments, indication device 1420 may be coupled to ESD 1410 by coupling 1412. Coupling 1412 may or may not be included as a component of indication device 1420. In some embodiments, coupling 1412 may be a substantially rigid solid which may remain in contact with monopolar plate 1402. Indication device coupling 1424 may couple indication device 1420 to any suitable interface (e.g., indicator interface 1352), device, system, network, or any combination thereof. For example, in some embodiments, indication device coupling 1424 may allow communication between indication device 1420 and a control system (e.g., control system 1350 of FIG. 13).

During charging or discharging, one or more characteristics of ESD 1410 may change. For example, in some embodiments, one or more components of ESD may undergo displacement substantially parallel to the direction of vector 1490, in response to charging, discharging, or both. Indication device 1420 may indicate the displacement of the one or more components of ESD 1410 by, for example, transmitting a signal or change in signal via indication device coupling 1424.

In some embodiments, indication device coupling 1424 may not be included with indication device 1420. For example, in some embodiments, indication device 1420 may be a stand-alone device. Indication device 1420 may, for example, display an indication, measurement, parameter, or other output associated with a kinetic response of ESD 1420 on any suitable display device or component (e.g., tick marks and reference mark, analog dial display, LCD display, LED display). In some embodiments, indication device 1420 may include memory hardware, processing circuitry, a power supply, any other suitable component (e.g., any suitable component of control system 1350 of FIG. 13), or any combination thereof.

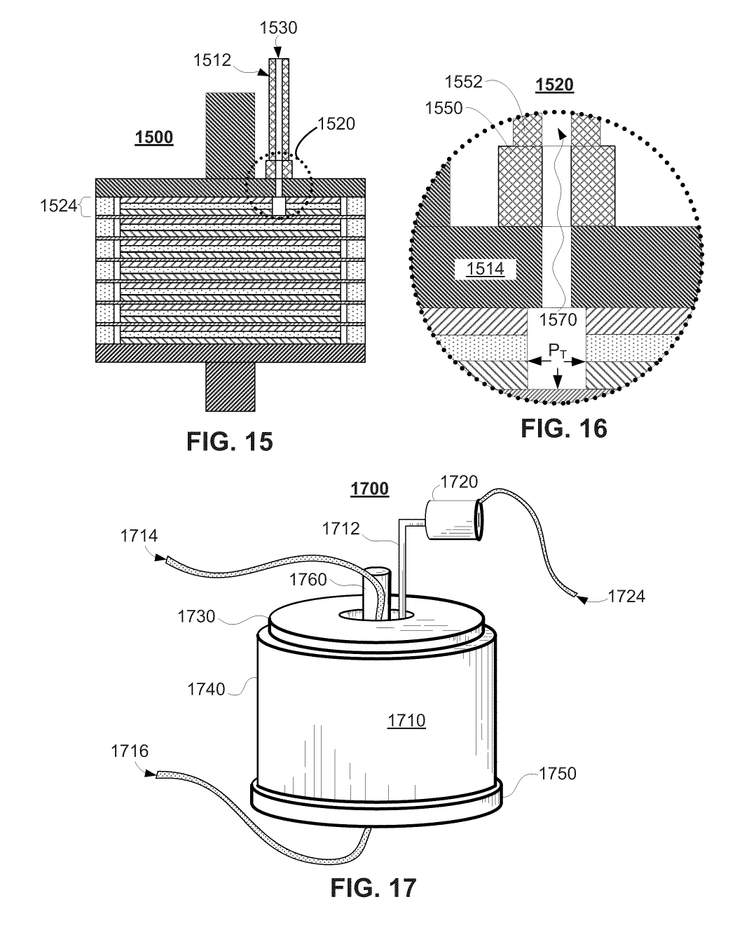

Shown in FIG. 15 is a cross-sectional view of an illustrative ESD 1500 which may include pressure tap 1512, in accordance with some embodiments of the present invention. Shown in FIG. 16 is an enlarged cross-sectional view of elements of FIG. 15, taken from dotted line 1520, in accordance with some embodiments of the present invention. Although not shown in FIG. 15, ESD 1500 may include any suitable components such as, for example, a wrapper, spring, compression plate, power leads, any other suitable components, or any combination thereof. In some embodiments, pressure tap 1512 may include a hole, recess or cavity in a suitable component (e.g., mono polar plate 1514, as shown in FIG. 16) of energy storage device 1500 to provide fluid access to conduit 1552. Although illustrative cell 1524 is shown with a cavity fluidly coupled to conduit 1512, in some embodiments, a cell need not include a cavity to be fluidly coupled to a pressure tap.

Pressure tap 1512 may include, for example, conduit coupling 1550 and conduit 1552. Conduit 1552 may be, for example, a tube, pipe, hose, manifold, any other suitable sealed conduit made of any suitable material including, for example, metal, plastic, rubber, any other suitable material or any combination or composites thereof. Conduit coupling 1550 may be any suitable type of coupling (e.g., compression fittings, pipe fittings, barbed hose fittings, clamped vacuum-type fittings, soldered connections, welded connections, brazed connections) or combination of couplings (e.g., pipe thread to compression tube fitting adapter fitting). Conduit 1552 may be any suitable shape, and may extend any suitable distance from energy storage device 1500.

In some embodiments, end 1530 may couple to an indication device which may indicate pressure. An additional conduit coupling (not shown) may be used at end 1530 to couple conduit 1552 to the indication device. Energy storage device 1500 may, in some embodiments, include more than one pressure tap, which may be coupled to one or more cells of energy storage device 1500.

Path 1570 shown in FIG. 16 may represent a substantially contiguous fluid path extending to end 1530. In some embodiments, path 1570 may extend within conduit 1552 to an indication device which may be coupled to conduit 1552. For example, pressure “P_{T}” in cell 1524 may be exerted on the surfaces of components included in cell 1524. The fluid within conduit 1552 may have a static pressure substantially the same as or different from “P_{T}” along path 1570. In some embodiments, there may be non-steady fluid flow along path 1570 during, for example, pressure equilibration or change within conduit 1552 which may accompany charging or discharging of energy storage device 1500.

Shown in FIG. 17 is illustrative system 1700 including ESD 1710 coupled to indication device 1720, in accordance with some embodiments of the present invention. Indication device 1720 may include a pressure sensor, pressure transducer, gas sensor (e.g., tunable diode laser sensor, electrochemical sensor), temperature sensor (e.g., thermocouple probe, thermistor, resistive thermal device), any other suitable indication device, or any combination thereof.

In some embodiments, compression plate 1730 may be bolted, pressed, or otherwise rigidly affixed to other components included in ESD 1710, such as, for example, wrapper 1740, or a spring. In some embodiments, compression plate 1730 may distribute a compressive force to one or more components of ESD 1710. Monopolar plate 1760 may, for example, be electrically coupled to power lead 1714. Power lead 1714 may, along with power lead 1716, couple ESD 1710 to an external power control circuit (e.g., power control circuitry 1356), external device, external network, or any other suitable system or combination of systems. In some embodiments, power leads 1714 and 1716 may correspond substantially to coupling 1314 of FIG. 13.

ESD 1710 may be in contact with or otherwise coupled to mounting coupling 1750. Mounting coupling 1750 may include, for example, a stand, frame, bracket, mounting coupling, any other suitable component, or any combination thereof which may provide a mount for ESD 1710. Any of the components of system 1400 shown in FIG. 14, or any additional components, may be implemented in system 1700 in accordance with the present invention.

In some embodiments, indication device 1720 may be coupled to ESD 1710 by fluid coupling 1712. Fluid coupling 1712 may or may not be included as a component of indication device 1720. In some embodiments, coupling 1712 may be a substantially hollow conduit which may be coupled to monopolar plate 1760. In some embodiments, fluid coupling 1712 may correspond substantially to pressure tap 1512 of FIGS. 15 and 16, which may include any suitable type of conduit, fitting, valve, pressure regulator, vent, any other suitable hardware, or any combination thereof. Fluid coupling 1712 may have any suitable shape, size, length, or any other property, and may be made of any suitable material or combination of materials (e.g., brass, steel, aluminum, rubber, plastic, polytetrafluoroethylene).

Indication device coupling 1724 may couple indication device 1720 to any suitable interface (e.g., indicator interface 1352), device, system, network, or any combination thereof. For example, in some embodiments, indication device coupling 1724 may allow communication between indication device 1720 and a control system (e.g., control system 1350 of FIG. 13). In some embodiments, indication device 1720 may receive signals (e.g., power signals, reference signals) via indication device coupling 1724 from a control system, network, device, any other suitable signal source, or any combinations thereof.

During charging or discharging, one or more characteristics of ESD 1710 may change. For example, in some embodiments, the pressure acting on one or more surfaces within ESD 1710 (e.g., surfaces within a cell exposed to a cell pressure) may change in response to charging, discharging, or both. Indication device 1720 may indicate the pressure, change in pressure, or both, acting on one or more surfaces of ESD 1710 by, for example, transmitting a signal or change in signal via indication device coupling 1724.

In some embodiments, indication device coupling 1724 may not be included with indication device 1720. For example, in some embodiments, indication device 1720 may be a stand-alone device. Indication device 1720 may, for example, display an indication, measurement, parameter, or other output associated with a kinetic response of ESD 1720 on any suitable display device or component (e.g., analog dial display, LCD display, LED display). In some embodiments, indication device 1720 may include memory hardware, processing circuitry, a power supply, any other suitable component (e.g., any suitable component of control system 1350 of FIG. 13), or any combination thereof.

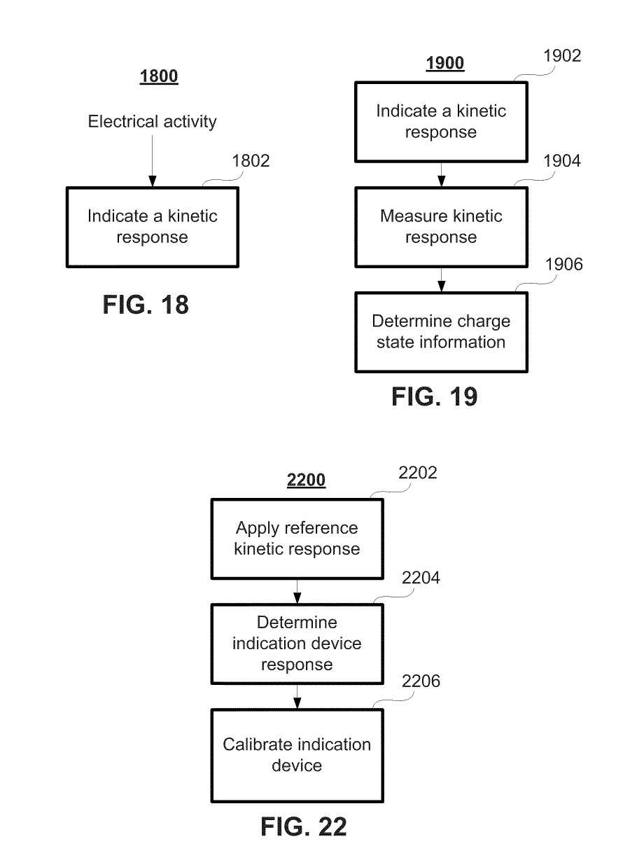

FIG. 18 is flow diagram 1800 of illustrative steps for indicating a kinetic response, in accordance with some embodiments of the present invention. At step 1802, a kinetic response may be indicated by an indication device. Electrical activity of an ESD may cause at least one kinetic response such as, for example, a pressure or change in pressure acting on a surface, a force or change in force acting on a component, or a displacement or displacement of one or more components.

Step 1802 may include, for example, transmission of a signal (e.g., optical signal, electrical signal, audible signal) via one or more couplings, storing one or more metrics (e.g., measurements, computed values based on measurements), displaying one or more metrics, initiating an event (e.g., alarm, switch activation), or any other suitable steps for indicating a kinetic response of an ESD, or any combination thereof. In some embodiments, step 1802 may include transmission of continuous or discreet signals such as, for example, analog signals and digital signals between an indication device (e.g., indication device 1320 of FIG. 13, indication device 1420 of FIG. 14, indication device 1720 of FIG. 17) and a control system (e.g., control system 1350 of FIG. 13).

Step 1802 need not include a quantitative indicator. For example, at step 1802, an indication device may indicate that a kinetic response has changed, but need not provide any quantitative measure of the change. In an illustrative example, an indication device such as a linear displacement sensor may indicate that suitable components of an ESD have undergone a linear displacement (e.g., caused by electrical activity of the ESD), but the indication device need not provide any quantitative measure of the displacement.

FIG. 19 is flow diagram 1900 of illustrative steps for determining charge information, in accordance with some embodiments of the present invention. Step 1902 may include indicating a kinetic response of an ESD which may undergo charging, discharging, or both. Step 1904 may include measuring a kinetic response of the ESD. Step 1906 may include determining charge information associated with the ESD.

Indicating a kinetic response, as shown by step 1902 of FIG. 19, may be performed using any suitable indication device. Step 1902 may include, for example, sending a signal or change in signal via a coupling (e.g., coupling 1324) to a control system (e.g., control system 1350), storing one or more metrics (e.g., in processing circuitry 1354) based in part on the indication, displaying one or more metrics based in part on the indication, initiating an event, any other suitable response, or any combination thereof. In some embodiments, step 1902 may include transmission of continuous or discreet signals such as, for example, analog signals and digital signals between an indication device and a control system.

Step 1904 of FIG. 19 may include, for example, determining a measurement based in part on an indication device signal, computing a metric based in part on an indication device signal, applying a correlation to an indication device signal, searching a database (e.g., catalogued parameter library) for a catalogued value, any other suitable computation process, or any combination thereof. Step 1904 may be performed by any suitable combination of hardware (e.g., control system 1350), software, or both. For example, in some embodiments, a control system may receive indication signals from an indication device via a communication coupling.

At step 1904, a control system may use processing circuitry to execute software commands to, for example, compute a parameter or a change in a parameter based in part on an indication signals. Parameters may include, for example, a displacement in suitable units (e.g., inches, millimeters, cubic centimeters), a force in suitable units (e.g., Newton, pound), a pressure in suitable units (e.g., pascal, torr, bar), any other suitable parameters, or any combination thereof. In some embodiments, parameters may be suitably normalized or non-dimensionalized by, for example, dividing by a reference value of suitable units, combining with other parameters, or any other suitable parameter modification or combination thereof. In some embodiments, normalization, non-dimensionalization, or both, of suitable parameters may improve accuracy during computation.

In some embodiments, step 1904 may be performed by a suitable measurement device. A measurement device, may include an indication device, processing circuitry, memory, calibration device, any other suitable hardware, any suitable communication couplings, or any suitable combination thereof. For example, in some embodiments, a measurement device may include an indication device such as a pressure transducer, and processing circuitry, which may be electrically coupled together via a suitable wire bundle. The measurement device may perform a measurement of a kinetic response based at least in part on an indication of a kinetic response of an ESD from the indication device.

Step 1906 may include determining charge information of a particular including, for example, state of charge, ESD robustness, any other suitable information, or any combination thereof. In some embodiments, state of charge may be a quantification of the residual charge of an ESD, ranging from fully discharged to fully charged, and, in some embodiments, overcharged. For example, a state of charge of 50% may indicate that an ESD has a remaining charge (e.g., suitable accumulated active materials) substantially halfway between fully discharged and fully charged. Robustness may be a quantification of cycle life, remaining cycle life, charge capacity, cell or stack impedance, component failure, any other suitable metric describing the relative vitality of an ESD, or any combination thereof.

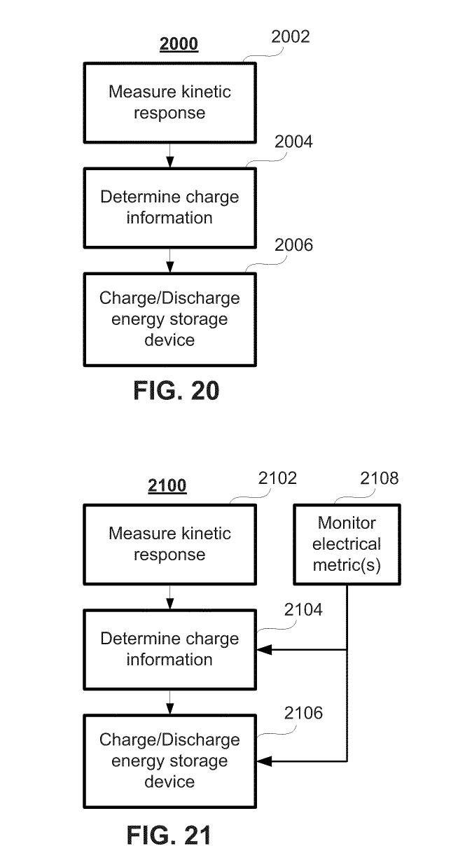

FIG. 20 is flow diagram 2000 of illustrative steps for controlling an ESD using an indication device, in accordance with some embodiments of the present invention. Step 2002 may include measuring a kinetic response corresponding to an ESD which may undergo charging, discharging, or both. Step 2004 may include determining charge information regarding the ESD. Step 2006 may include charging or discharging the ESD.

In some embodiments, one or more kinetic responses may be measured by a measurement device in accordance with step 2002. For example, in some embodiments, a measurement device may include an indication device which may indicate a kinetic response. The measurement device may include a suitable control system (e.g., control system 1350 of FIG. 13) which may be coupled to the indication device, and may receive signals from the indication device. The control system may compute a measurement associated with the kinetic response, based at least in part on the signal received from the indication device. In accordance with step 2004, the computed measurement may be used by the control system to determine charge information such as, for example, state of charge, change of state of charge, rate of change of state of charge, robustness, any other suitable information regarding the charge of an ESD, or any combination thereof. In accordance with step 2006, charge information may be used by the control system to, for example, control a rate of charging, a rate of discharging, or a schedule for charging, discharging, or both.

Step 2002 may include a measurement device performing any suitable measurement action which may include, for example, receiving an indication of a kinetic response, processing a signal from an included indication device (e.g., filtering, averaging, sampling, amplifying), computing a metric (e.g., determining a measurement value, scaling a measurement value), any other suitable action which may be performed to measure a kinetic response, or any combination thereof. The aforementioned measurement actions may be performed by any suitable control system such as, for example, control system 1350 of FIG. 13.

Step 2004 may include performing an action for determining charge information including, for example, computing charge information based at least in part on a measured value, searching a suitable database for charge information, recalling stored charge information, any other suitable process for determining charge information, or any combination thereof. For example, in some embodiments, a suitable control system may input a measured value into a particular formula (e.g., function, multi-variable mapping, probability distribution, discreet transform) to compute a state of charge value or a robustness value. In a further example, a suitable control system may search a database (e.g., an indexed look up table) stored on a memory device for a state of charge value or a robustness value. The control system may interpolate, recall, or otherwise select charge information from the memory device based on a measured value.

Step 2006 may include performing electrical control actions (e.g., charging, discharging, circuit breaking) in regards to any suitable ESD. For example, in some embodiments, any suitable control system may provide electrical charging to the ESD. The control system may, in some embodiments, provide a schedule for charging which may include set-points, limits, or other indicators regarding rates of charging, total charge, or any other suitable metric. A closed loop or open loop control strategy may be used by a control system to charge or discharge the ESD based at least in part on one or more measured values. For example, in some embodiments, a state space model may be used to compute a charging or discharging rate based on an input of a measured value. In a further example, an algebraic formulation may be used to compute a charging or discharging rate based on an input of a measured value.

FIG. 21 is flow diagram 2100 of illustrative steps for controlling an ESD using one or more indicating devices, and one or more measured electrical metrics, in accordance with some embodiments of the present invention. Step 2102 may include measuring a kinetic response corresponding to an ESD which may undergo charging, discharging, or both. Step 2104 may include determining charge information for the ESD. Step 2106 may include charging or discharging the ESD. At step 2108, one or more electrical metrics associated with the ESD may be measured. In some embodiments, a measurement of any suitable electrical metric (e.g., ESD operating voltage, ESD voltage-current relationship, ESD impedance) may be taken at step 2102, 2104, or 2106 to perform the respective actions of each step. Electrical metrics may be measured by any suitable measuring device such as, for example, a digital multimeter (DMM), an analog input channel of a control system, any other suitable measurement device, or any combination thereof.

In some embodiments, a kinetic response of an ESD such as a displacement, pressure or force may be measured by a measurement device. The measurement may be performed by a control system of the measurement device, based on a signal received from an indication device of the measurement device. At any particular time, the ESD may operate (e.g., provide or receive zero or nonzero current flow from a suitable potential difference) at a given operating voltage. The kinetic response measurement may be further based at least in part on, for example, the ESD operating voltage. In some embodiments, a combination of one or more signals from an indication device and one or more electrical metrics may be used to measure a kinetic response in accordance with step 2102.

In some embodiments, step 2104 may include determining charge information based at least in part on a measured kinetic response and at least in part on a measured electrical metric. In some embodiments, particular charge information (e.g., values of state of charge) may be mapped over various values of a measured kinetic response and a measured electrical metric. For example, state of charge may be formulated as a continuous function of both a measured displacement and a measured operating voltage. In a further example, state of charge may be formulated as a discreet function or mapping of both a measured displacement and a measured operating voltage. In a further example, robustness may be formulated as a conditional probability distribution function of a measured force, conditioned on a measured electrical impedance. The previous examples are illustrative, and are meant to demonstrate concepts, rather than limit the scope of the present disclosure. Any suitable mathematical or computational correspondence (e.g., functional relationship, correlation, probability distribution, arrangement in a look up table, interpolation of entries in a look up table) may be used to determine charge information based at least in part on a measured kinetic response and a measured electrical metric.

At step 2108, one or more electrical metrics may be monitored. For example, step 2108 may include computing an electrical metric (e.g., voltage, current, impedance) based on a signal from a measuring device (e.g., a DMM), performing an electrochemical impedance spectroscopy (EIS) measurement, performing a voltammetric measurement (e.g., cyclic voltammetry), performing a chronopotentiometric measurement (e.g., programmed current methods), any other suitable process or technique for measuring an electrical metric, or any combination thereof.

In an illustrative example, a control system may be coupled to a set of more than one indication devices, each coupled to an ESD (e.g., included in an EV). The kinetic response of each ESD may be indicated by the respective indication devices, and the indication(s) may be monitored by the control system. The control system may increase, decrease, or otherwise manage charging or discharging of each individual ESD relative to one or more other ESDs. For example, if a particular ESD undergoes charging or discharging at an increased rate relative to other ESDs, the control system may decrease the relative electrical energy extracted from or supplied to the particular ESD, and increase the relative electrical energy extracted from or supplied to one or more other ESDs.

FIG. 22 is flow diagram 2200 including illustrative steps for calibrating an indication device, in accordance with some embodiments of the present invention. Step 2202 may include applying a reference kinetic response to an indication device. Step 2204 may include determining a response of the indication device to the reference kinetic response. Step 2206 may include calibrating the indication device.

At step 2202, any suitable kinetic response may be applied to an indication device by a calibration device, ESD, or other apparatus which may provide a calibration reference (e.g., distance, force, pressure), or any combination thereof.

At step 2204, one or more responses of the indication device to a suitable kinetic response may be determined by a control system. For example, a reference kinetic response may be applied to an indication device. The indication device may provide a signal (e.g., a voltage) which may be received by a suitable control system. The control system may, for example, determine a measurement value, determine a difference between a predetermined value and an indication device signal or metric derived thereof, or other indicator based at least in part on the received signal from the indication device.

At step 2206, a control system may be used to calibrate the indication device. In some embodiments, the control system may determine calibration parameters, alter an indication device's response to a kinetic response, scale or otherwise manipulate a received signal from an indication device, any other suitable calibration technique, or any combination thereof. Step 2206 may be performed by hardware, software, or any suitable combination thereof.

In some embodiments, a conduit including a known reference gas pressure may be coupled to an indication device (e.g., a pressure transducer). The indication device may provide an output signal in response to the reference gas pressure. A control system may receive the output signal from the indication device, and determine a correlation between the received signal and the reference gas pressure value. For example, a pressure of 100 kPa may be applied to an indication device, which may output a signal of 100 milliVolts (mV) to a suitable control signal. The control system may determine one or more calibration parameters such that the control system computes a measured value of 100 kPa if a 100 mV signal is received from the indication device. In some embodiments, for example, the control system may compute a measured value based on a received signal from the indication device. For the previous example, the control system calibration may include the determination that 1 mV=1 kPa. Any suitable calibration curve, correlation, or other relationship may be established by a suitable control system for calibrating the output of a suitable indication device. In some embodiments, step 2206 may include determining a difference, tolerance, error, accuracy, or any other comparative indicator between a measured value derived from a signal received from an indication device and a reference value, or any combination thereof.

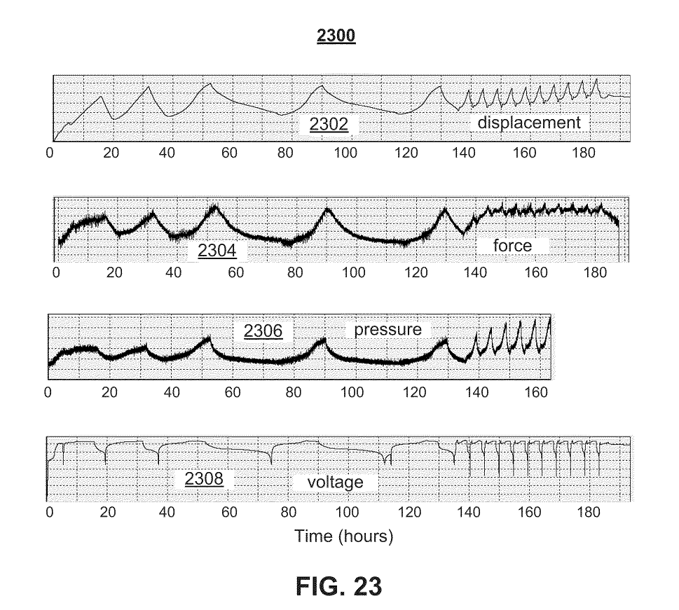

FIG. 23 is illustrative panel 2300 of time series of cell voltage and kinetic response, in accordance with some embodiments of the present invention. Panel 2300, with abscissa in units of hours, includes time series 2302 of displacement, time series 2304 of force, time series 2306 of pressure, and time series 2308 of operating voltage as measured for an exemplary ESD. The ordinate scales of the time series of panel 2300 are shown in arbitrary units, which may be different for each time series.

Time series 2302 of displacement represents an axial (e.g., stacking direction) displacement of the ESD as measured by a displacement sensor. Time series 2304 of force represents an axial force of the ESD as measured by a force transducer. Time series 2306 of pressure represents a cell pressure of the ESD as measured by a pressure transducer. Time series 2308 of operating voltage represents an operating voltage of the ESD as measured by a digital multimeter (DMM). The indication devices (e.g., sensor, transducer, DMM) used to indicate the physical responses represented in panel 2300 were coupled to a control system which performed measurement computations based at least in part on the indication device outputs.

At times of about 15, 32, 55, 90, and 130 hours in panel 2300, peaks can be seen in time series 2302, 2304, and 2306. The upstroke of the peaks may occur during charging of the ESD, and the downstroke of the peaks may occur during discharging of the ESD. At these same times, time series 2308 shows a plateau followed by a decrease. The plateau may correspond to the charging of the ESD, while the decrease may correspond to discharging of the ESD. The substantially simultaneous behavior of time series 2302, 2304, 2306 and 2308 at times 15, 32, 55, 90, and 130 hours suggests that charge information may be derived at least in part from indications of kinetic response. For example, time series 2308 may be relatively insensitive to time during the charging periods just before times 15, 32, 55, 90, and 130 hours. Time series 2302, 2304, and 2306 may be relatively more sensitive to time during the charging periods just before times 15, 32, 55, 90, and 130 hours.

In reference to panel 2300, beginning at a time of about 135 hours and extending to a time of about 185 hours, oscillatory behavior can be seen in time series 2302, 2304, 2306 and 2308, which may be caused by relatively rapid successive charging and discharging of the ESD. Ten peaks can be seen in time series 2302, 2304, and 2308, while only the first six peaks can be seen in time series 2306. The coherency of the oscillatory behavior in various kinetic and voltage responses suggests that charge information may be derived at least in part from one or more indications of kinetic response to charging/discharging processes. In some embodiments, a frequency response (e.g., to a periodic perturbation) of one or more kinetic responses may be monitored to determine ESD charge information, ESD robustness, or both.

In some embodiments, changes in ESD charge information may be derived at least in part from temporal behavior of one or more ESD characteristics, parameters derived from indications or measurements, or changes thereof, of the ESD. For example, parameters derived from one or more time series such as peak height, rate of change, baseline offset, frequency response, or any other suitable parameter or change in parameter, or any combination thereof may be used to determine charge information, ESD robustness, or both. For example, with reference to panel 2300 of FIG. 23, the peak heights of time series 2302, 2304, and 2306 at times of 15, 32, 55, 90, and 130 hours may provide information regarding the state of charge of the ESD. Peak heights of relatively larger value may correspond to increased depth of charge. Similarly, an increase of depth in the valleys located between the peaks may correspond to increased depth of discharge. ESD robustness may also be determined based at least in part on, for example, peak height. For example, a reduced peak height resulting from a particular charging or discharging process may correspond to reduced ESD cycle life or charge capacity.

In some embodiments, an indication device may be used to indicate one or more kinetic responses of an ESD independent of a voltage measurement, whether or not a voltage measurement is performed on the ESD. For example, an indication device may be used to indicate displacement, and may not be electrically connected to terminals of the ESD. Because a voltage measurement typically requires an electrical connection to terminals of the ESD, the indication of displacement may be substantially independent from any voltage measurement which may be taken, and independent from any charging or discharging which may occur. One or more indication devices may indicate any suitable combination of kinetic responses, in concert with or without a voltage measurement, in order to determine charge information.

In some embodiments, a particular kinetic response may be used to provide a relatively more sensitive determination of charge information. In some embodiments, different kinetic responses may be used in different operating regimes (e.g., states of charge) to determine charge information. For example, with reference to FIG. 23, a peak is observed in time series 2302, 2304, and 2306, at around a time of 90 hours around the point where the ESD is switched from being charged to being discharged. At the same time of 90 hours, time series 2308 displays a relatively less pronounced feature. During such conditions (e.g., near the charge-discharge switch near 90 hours in FIG. 23), for example, charge information may be derived based at least in part on one or more indicated kinetic responses, rather than a voltage measurement, which may allow more resolution in determining the charge information.

It will be understood that the foregoing is only illustrative of the principles of the invention, and that various modifications may be made by those skilled in the art without departing from the scope and spirit of the invention. It will also be understood that various directional and orientational terms such as “horizontal” and “vertical,” “top” and “bottom” and “side,” “length” and “width” and “height” and “thickness,” “inner” and “outer,” “internal” and “external,” and the like are used herein only for convenience, and that no fixed or absolute directional or orientational limitations are intended by the use of these words. For example, the devices of this invention, as well as their individual components, may have any desired orientation. If reoriented, different directional or orientational terms may need to be used in their description, but that will not alter their fundamental nature as within the scope and spirit of this invention. Those skilled in the art will appreciate that the invention may be practiced by other than the described embodiments, which are presented for purposes of illustration rather than of limitation, and the invention is limited only by the claims that follow.

What is claimed is:

1. A method for providing an indication of state of charge of an energy storage device, the method comprising:
indicating a kinetic response to an electrical activity in the energy storage device using an indication device, wherein the state of charge is determinable from the indication of the kinetic response.

2. The method of claim 1, further comprising providing a measurement of the kinetic response based at least in part on the indication of the kinetic response.

3. The method of claim 1, further comprising determining the state of charge of the energy storage device based at least in part on the indication of the kinetic response.

4. The method of claim 1, wherein the kinetic response comprises a displacement of at least one component of the device.

5. The method of claim 4, wherein the displacement is a substantially linear displacement.

6. The method of claim 1, wherein the kinetic response comprises a change in gas pressure within the energy storage device.

7. The method of claim 1, wherein the kinetic response comprises a change in force in the energy storage device.

8. The method of claim 1, further comprising generating an indication of robustness based at least in part on the indication of the kinetic response.

9. The method of claim 1, further comprising calibrating the indication of the kinetic response relative to a reference kinetic response.

10. A method for controlling state of charge of an energy storage device, the method comprising:
measuring a kinetic response of the energy storage device using a measurement device;
determining charge information of the energy storage device based at least in part on the measured kinetic response; and
causing the state of charge of the energy storage device to change based at least in part on the determined charge information.

11. The method of claim 10, wherein causing the state of charge of the energy storage device to change further comprises one of charging or discharging the energy storage device.

12. The method of claim 10, wherein causing the state of charge of the energy storage device to change further comprises causing the rate of change of the state of charge of the energy storage device to change.

13. A system for indicating state of charge of an energy storage device, the system comprising:
an indication device configured to be coupled to the energy storage device, wherein the indication device indicates at least one kinetic response of the energy storage device from which state of charge is determinable.

14. The system of claim 13, further comprising processing circuitry coupled to the indication device and configured to:
receive the indication of the kinetic response from the indication device; and
provide a measurement of the kinetic response based at least in part on the indication of the kinetic response.

15. The system of claim 14, wherein the processing circuitry is further configured to determine charge information based at least in part on the measurement of the kinetic response.

16. The system of claim 14, further comprising power control circuitry electrically coupled to both the processing circuitry and the energy storage device, wherein the power control circuitry is configured to charge or discharge the energy storage device.

17. The system of claim 13, wherein the indication device comprises a linear displacement sensor.

18. The system of claim 13, wherein the indication device comprises a force transducer.

19. The system of claim 13, wherein the indication device comprises a pressure transducer.

20. The system of claim 13, wherein the indication device comprises an optical sensor.
